(19) United States
(12) Patent Application Publication
(10) Pub. No.: US 2026/0068381 A1
(43) Pub. Date: Mar. 5, 2026

(54) DISPLAY APPARATUS, ELECTRONIC DEVICE, AND METHOD OF MANUFACTURING DISPLAY APPARATUS

(71) Applicant: Samsung Display Co., Ltd., Yongin-si (KR)

(72) Inventors: Sunghwan Youn, Yongin-si (KR); Kihyun Kim, Yongin-si (KR)

(21) Appl. No.: 19/081,716

(22) Filed: Mar. 17, 2025

(30) Foreign Application Priority Data
Aug. 30, 2024 (KR) 10-2024-0117888

(51) Int. Cl. H10H 29/37; G06F 3/044; H10H 29/01

(52) U.S. Cl. CPC H10H 29/37; G06F 3/0445; H10H 29/012

(57) ABSTRACT

A display apparatus that includes a substrate including a display area, an opening area in the display area, and an intermediate area between the opening area and the display area is provided. The display apparatus includes a light-emitting diode provided in the display area and including a sub-pixel electrode, a counter electrode, and an intermediate layer between the sub-pixel electrode and the counter electrode, a planarization layer on the light-emitting diode, a first touch electrode layer on the planarization layer, a first touch insulating layer on the first touch electrode layer, a second touch electrode layer on the first touch insulating layer, a second touch insulating layer on the second touch electrode layer, and at least one partition wall located adjacent to the opening area in the intermediate area and on the second touch insulating layer.

### CROSS-REFERENCE TO RELATED APPLICATION

This application claims priority to and the benefit of Korean Patent Application No. 10-2024-0117888, filed on Aug. 30, 2024, in the Korean Intellectual Property Office, the entire disclosure of which is incorporated herein by reference.

### BACKGROUND

### 1. Field

One or more aspects of embodiments of the present disclosure relate to a display apparatus, an electronic device including the display apparatus, and a method of manufacturing the display apparatus. The display apparatus may include a light-emitting diode as a display element.

### 2. Description of the Related Art

Recently, display apparatuses have been used for one or more suitable purposes, and one or more suitable functions combined or associated with display apparatuses have been proposed. One or more suitable methods have been proposed to add one or more suitable functions while securing or maintaining the basic functions of display apparatuses that display images.

For example, an electronic device may include a display apparatus, and may include a component for performing another function, in addition to the display apparatus displaying an image. For example, the electronic device may include a component such as a camera or a sensor. The component may be on a rear surface of the display apparatus. In order for the component to smoothly perform its functions, the display apparatus may have an opening defined in an area overlapping the component. In this case, the opening may be defined by passing through the display apparatus, and may be formed by forming a plurality of layers on a substrate and then etching the plurality of layers and the substrate. A process of etching the plurality of layers and a process of etching the substrate may be performed simultaneously or independently.

### SUMMARY

One or more aspects of embodiments of the present disclosure are directed toward a display apparatus that may include a light-emitting diode as a display element.

One or more aspects of embodiments of the present disclosure are directed toward a method of manufacturing the display apparatus, for example, a method for forming an opening in the display apparatus.

As an example of the method for forming the opening in the display apparatus, a method of etching a plurality of layers from top surfaces thereof and etching a substrate from a rear surface thereof may be utilized. In this method, the opening formed by etching the plurality of layers may be filled with an insulating layer functioning as a buffer, the substrate may be etched, and then the insulating layer may be removed. When the insulating layer is removed, undesired lifting and/or peeling of the plurality of layers may occur due to an adhesive force between the insulating layer and the plurality of layers. This may lead to a decrease in the quality of the display apparatus, and thus, a method to avoid the lifting and/or peeling is desired or required.

However, it should be noted that these objectives are merely examples, and the scope of the disclosure is not limited to the herein-mentioned aspects. Rather, other objectives of one or more embodiments of the present disclosure will be apparent to those skilled in the art from the following descriptions.

Additional aspects of one or more embodiments will be set forth in part in the description which follows and, in part, will be apparent from the description, or may be learned by practice of the presented embodiments.

According to one or more embodiments, a display apparatus includes a substrate including a display area, an opening area in the display area, and an intermediate area between the opening area and the display area, a light-emitting diode in the display area and including a sub-pixel electrode, a counter electrode, and an intermediate layer between the sub-pixel electrode and the counter electrode, a planarization layer on the light-emitting diode, a first touch electrode layer on the planarization layer, a first touch insulating layer on the first touch electrode layer, a second touch electrode layer on the first touch insulating layer, a second touch insulating layer on the second touch electrode layer, and at least one partition wall located adjacent to the opening area in the intermediate area and on the second touch insulating layer.

In one or more embodiments, each of the substrate, the planarization layer, the first touch insulating layer, and the second touch insulating layer may include an opening overlapping the opening area.

In one or more embodiments, the at least one partition wall may at least partially be around (e.g., surround) the opening area.

In one or more embodiments, the at least one partition wall may include a plurality of partition walls, and the plurality of partition walls may concentrically be around (e.g., surround) the opening area.

In one or more embodiments, the at least one partition wall may include an organic insulating material.

In one or more embodiments, the at least one partition wall may include a same material as the second touch insulating layer.

According to one or more embodiments, an electronic device includes a display apparatus including a display area, an opening area in the display area, and an intermediate area between the opening area and the display area, and a component under a rear surface of the display apparatus and overlapping the opening area of the display apparatus, wherein the display apparatus includes a substrate, a light-emitting diode in the display area and including a sub-pixel electrode, a counter electrode, and an intermediate layer between the sub-pixel electrode and the counter electrode, a planarization layer on the light-emitting diode, a first touch electrode layer on the planarization layer, a first touch insulating layer on the first touch electrode layer, a second touch electrode layer on the first touch insulating layer, a second touch insulating layer on the second touch electrode layer, and at least one partition wall located adjacent to the opening area in the intermediate area and on the second touch insulating layer.

In one or more embodiments, each of the substrate, the planarization layer, the first touch insulating layer, and the second touch insulating layer may include an opening overlapping the opening area.

In one or more embodiments, the at least one partition wall may at least partially be around (e.g., surround) the opening area.

In one or more embodiments, the at least one partition wall may include a plurality of partition walls, and the plurality of partition walls may concentrically surround the opening area.

In one or more embodiments, the at least one partition wall may include an organic insulating material.

In one or more embodiments, the at least one partition wall may include a same material as the second touch insulating layer.

According to one or more embodiments, a method of manufacturing a display apparatus includes providing or arranging, on a substrate including a display area, an opening area in the display area, and an intermediate area between the opening area and the display area, a light-emitting diode in the display area, sequentially providing or arranging, on the light-emitting diode, a planarization layer, a first touch electrode layer, a first touch insulating layer, a second touch electrode layer, and a second touch insulating layer, providing or arranging at least one partition wall adjacent to the opening area, on the second touch insulating layer, forming a first opening overlapping the opening area, in the planarization layer, the first touch insulating layer, and the second touch insulating layer, filling the first opening with a first temporary layer, forming a second opening overlapping the opening area, in the substrate, and removing the first temporary layer.

In one or more embodiments, the at least one partition wall may be around (e.g., surround) the opening area, and a part of the first temporary layer may contact (e.g., be on) a side surface of the at least one partition wall.

In one or more embodiments, the at least one partition wall may include a third opening overlapping the opening area, and the first temporary layer may at least partially fill the third opening.

In one or more embodiments, the first temporary layer may be in the opening area.

In one or more embodiments, the providing or arranging of the at least one partition wall may include providing or arranging a plurality of partition walls, wherein a portion (e.g., some) of the plurality of partition walls are in the opening area, wherein the method further includes removing the portion (e.g., some) of the plurality of partition walls in the opening area.

In one or more embodiments, the method may further include providing or arranging a second temporary layer on the first temporary layer, wherein the removing of the first temporary layer includes removing the first temporary layer and the second temporary layer simultaneously (e.g., together).

In one or more embodiments, the at least one partition wall may include a same material as the second touch insulating layer, and the providing or arranging of the at least one partition wall may include etching the second touch insulating layer.

In one or more embodiments, the at least one partition wall may include an organic insulating material, and the providing or arranging of the at least one partition wall may include providing or arranging the at least one partition wall by using an inkjet method.

### BRIEF DESCRIPTION OF THE DRAWINGS

The accompanying drawings are included to provide a further understanding of the preceding and other aspects, features, and advantages of one or more embodiments of the present disclosure and are incorporated in and constitute a part of this specification. The drawings illustrate example embodiments that will be more apparent from the following description taken in conjunction with the accompanying drawings. In the drawings:

FIG. 1 is a schematic perspective view illustrating an electronic device, according to one or more embodiments;

FIG. 2 is a schematic cross-sectional view illustrating an electronic device, according to one or more embodiments;

FIG. 3 is a circuit diagram schematically illustrating a light-emitting diode provided in one pixel of a display apparatus and a pixel circuit connected to the light-emitting diode, according to one or more embodiments;

FIG. 4 is a cross-sectional view illustrating a portion of a display area of a display apparatus, according to one or more embodiments;

FIG. 5 is a plan view illustrating a part of a display apparatus, according to one or more embodiments;

FIG. 6 is a cross-sectional view illustrating a display apparatus, according to one or more embodiments;

FIGS. 7A, 7B, 7C, 7D, 7E, 7F, and 7G are cross-sectional views illustrating processes of a method of manufacturing a display apparatus, according to one or more embodiments;

FIGS. 8A and 8B are cross-sectional views illustrating processes of a method of manufacturing a display apparatus, according to one or more embodiments; and

FIG. 9 is a cross-sectional view illustrating one process in a method of manufacturing a display apparatus, according to one or more embodiments.

### DETAILED DESCRIPTION

Reference will now be made in more detail to embodiments, examples of which are illustrated in the accompanying drawings, wherein like reference numerals refer to like elements throughout. In this regard, the present disclosure has embodiments that may have different forms and should not be construed as being limited to the descriptions set forth herein. Rather, these embodiments are provided so that this disclosure will be thorough and complete, and will fully convey the scope of the present disclosure to those skilled in the art. Accordingly, the embodiments are merely described herein, by referring to the figures, to explain aspects of example embodiments of the present description.

As used herein, the term “and/or” includes any and all combinations of one or more of the associated listed items. Throughout the disclosure, the expression “at least one of a, b or c” indicates: only a, only b, only c; both (e.g., simultaneously) a and b; both (e.g., simultaneously) a and c; both (e.g., simultaneously) b and c; all of a, b, and c; or variations thereof.

As the disclosure allows for one or more suitable changes and numerous embodiments, certain embodiments will be illustrated in the drawings and described in the detailed description. Effects and features of the disclosure, and methods for achieving them will be clarified with reference to embodiments described herein in more detail with reference to the drawings. However, the subject matter of the disclosure is not limited to the following embodiments and may be embodied in one or more suitable forms.

Hereinafter, one or more embodiments will be described in detail with reference to the accompanying drawings, wherein the same or corresponding elements are denoted by the same reference numerals throughout and a repeated description thereof is omitted.

Although the terms “first,” “second,” and/or the like may be used to describe one or more suitable elements, these elements should not be limited by these terms. These terms are only used to distinguish one element from another. These terms are only used to distinguish one element from another element. For instance, a first element discussed herein could be termed a second element without departing from the teachings of the present disclosure. Similarly, the second element could also be termed the first element.

As used herein, the singular forms “a,” “an,” and “the” are intended to include the plural forms as well, unless the context clearly indicates otherwise.

It will be further understood that the terms “includes,” “include,” “including,” “has,” “have,” “having,” “comprise,” “comprises,” and “comprising,” as used herein specify the presence of stated features or components, but do not preclude the presence or addition of one or more other features or components.

It will be further understood that, when a layer, region, or component is referred to as being “on” another layer, region, or component, it may be directly on the other layer, region, or component, or may be indirectly on the other layer, region, or component with intervening layers, regions, or components therebetween.

Spatially relative terms, such as “beneath,” “below,” “lower,” “above,” “upper,” “bottom,” “top,” and/or the like, may be used herein for ease of description to describe one element or feature's relationship to another element(s) or feature(s) as illustrated in the drawings. It will be understood that the spatially relative terms are intended to encompass different orientations of the device in use or operation in addition to the orientation depicted in the drawings. For example, if the device in the drawings is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

Sizes of components in the drawings may be exaggerated or reduced for convenience of explanation. For example, because sizes and thicknesses of components in the drawings may be arbitrarily illustrated for convenience of explanation, the disclosure is not limited thereto.

When a certain embodiment may be implemented differently, a specific process order may be different from the described order. For example, two consecutively described processes may be performed substantially at the same time or may be performed in an order opposite to the described order.

“A and/or B” is used herein to select only A, select only B, or select both A and B. “At least one of A or B” is used to select only A, select only B, or select both A and B.

It will be understood that when a layer, a region, or a component is referred to as being “coupled” or “connected” to another layer, region, or component, it may be “directly coupled” or “directly connected” to the other layer, region, or component and/or may be “indirectly coupled” or “indirectly connected” to the other layer, region, or component with other layers, regions, or components interposed therebetween. For example, when a layer, a region, or a component is referred to as being “electrically connected,” it may be directly electrically connected, and/or may be indirectly electrically connected with intervening layers, regions, or components therebetween.

The x-axis, the y-axis and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

The term “may” will be understood to refer to “one or more embodiments of the present disclosure,” some of which include the described element and some of which exclude that element and/or include an alternate element. Similarly, alternative language such as “or” refers to “one or more embodiments of the present disclosure,” each including a corresponding listed item.

Unless otherwise defined, all chemical names, technical and scientific terms, and terms defined in common dictionaries should be interpreted as having meanings consistent with the context of the related art, and should not be interpreted in an ideal or overly formal sense.

In this context, “consisting essentially of” indicates that any additional components will not materially affect the chemical, physical, optical or electrical properties of the semiconductor film.

Further, in this specification, the phrase “plan view,” indicates viewing a target portion from the top, and the phrase “on a cross-section” indicates viewing a cross-section formed by vertically cutting a target portion from the side.

### Electronic Device

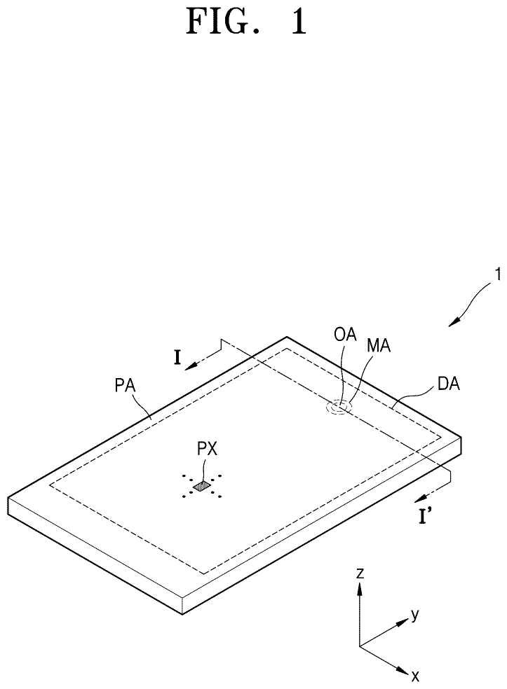

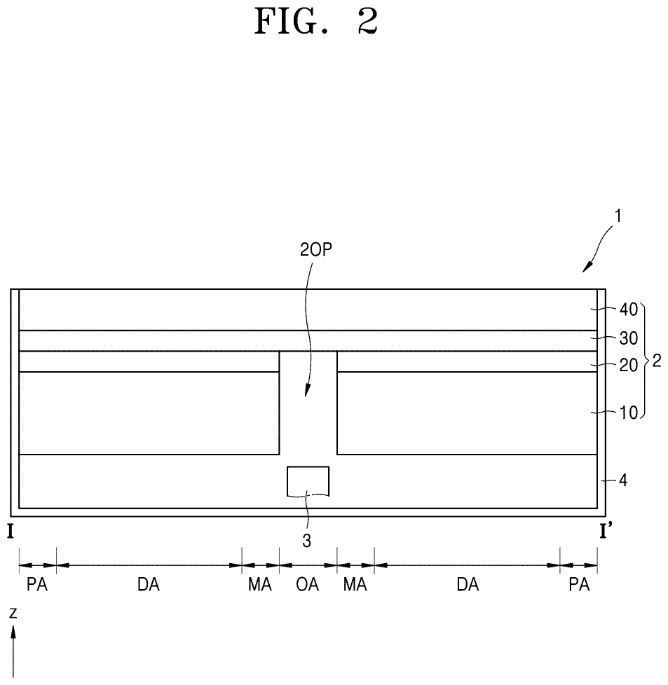

FIG. 1 is a schematic perspective view illustrating an electronic device, according to one or more embodiments. FIG. 2 is a schematic cross-sectional view illustrating an electronic device, according to one or more embodiments. FIG. 2 may be a cross-sectional view illustrating the electronic device taken along line I-I′ of FIG. 1.

Referring to FIGS. 1 and 2, an electronic device 1 may include a display apparatus 2, a component 3, and a housing 4. In one or more embodiments, the display apparatus 2 and the component 3 may be accommodated in the housing 4.

The electronic device 1 may include any of one or more suitable products such as a television, a laptop computer, a monitor, an advertisement board, or an Internet of things (IoT) device as well as a portable electronic device such as a mobile phone, a smartphone, a tablet personal computer (PC), a mobile communication terminal, an electronic organizer, an electronic book, a portable multimedia player (PMP), a navigation device, or an ultra-mobile PC (UMPC). Also, the electronic device 1 according to one or more embodiments may include a wearable device such as a smart watch, a watch phone, a glasses-type display, or a head-mounted display (HMD). Also, the electronic device 1 according to one or more embodiments may include a center information display (CID) on an instrument panel, a center fascia, or a dashboard of a vehicle, a room mirror display replacing a side-view mirror of a vehicle, or a display on the back of a front seat for entertainment for an occupant in a back seat of a vehicle. The display apparatus 2 may be included, as an element to display a moving image or a still image in one or more embodiments of the electronic devices 1 described herein, in the electronic device 1. Although the electronic device 1 is a smartphone in FIG. 1, the disclosure is not limited thereto.

The electronic device 1 may have a substantially rectangular shape in a plan view. For example, as shown in the embodiment of FIG. 1, the electronic device 1 may have a rectangular planar shape having a short side in an x-direction and a long side in a y-direction in a plan view. A corner where the short side in the x-direction and the long side in the y-direction meet each other may be rounded to have a certain curvature or formed to have a right angle. A planar shape of the electronic device 1 is not limited to a rectangular shape, and may be any of other shapes such as a polygonal shape, an elliptical shape, or an irregular shape. A shape of the display apparatus 2 may at least partially correspond to a shape of the electronic device 1.

The electronic device 1 may include an opening area OA, and a display area DA at least partially around (surrounding) the opening area OA. The electronic device 1 may include an intermediate area MA located between the opening area OA and the display area DA. The intermediate area MA may have a closed-loop shape entirely around (surrounding) the opening area OA in a plan view. The electronic device 1 may include a peripheral area PA located outside the display area DA. The peripheral area PA may be around (surround) the display area DA.

The opening area OA may be inside the display area DA. In one or more embodiments, the opening area OA may be in an upper center portion of the display area DA as shown in FIG. 1. In embodiments, the opening area OA may be in one or more suitable ways. For example, the opening area OA may be in an upper left portion of the display area DA or an upper right portion of the display area DA. Although one opening area OA is illustrated in FIG. 1, in another embodiment, a plurality of opening areas OA may be provided.

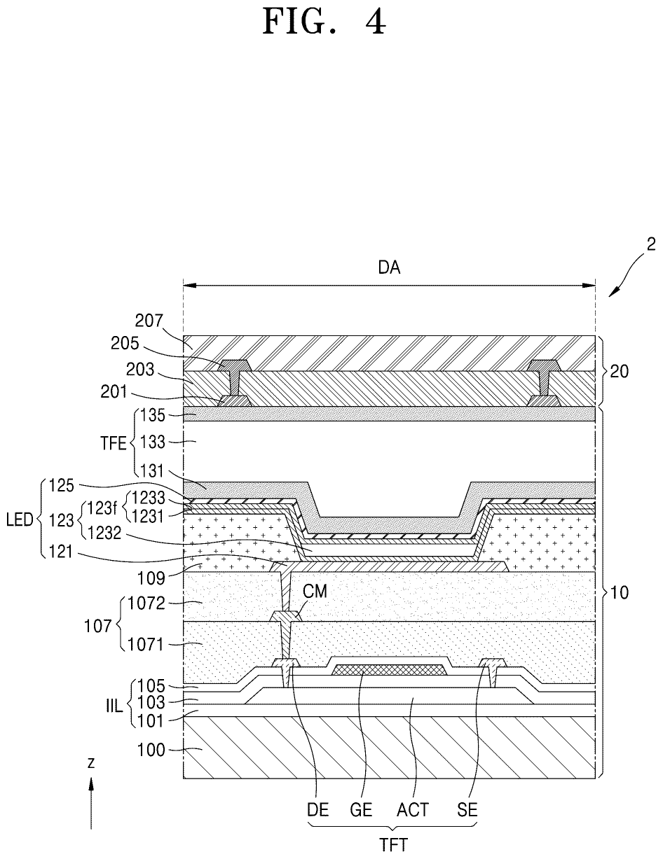

Because the electronic device 1 includes the display apparatus 2, the display apparatus 2 may include the opening area OA, the display area DA, the intermediate area MA, and the peripheral area PA. In embodiments, because the display apparatus 2 includes a substrate 100 (see FIG. 4), the substrate 100 may include the opening area OA, the display area DA, the intermediate area MA, and the peripheral area PA. In embodiments, the opening area OA, the display area DA, the intermediate area MA, and the peripheral area PA are located or defined on the substrate 100.

The electronic device 1 may display an image through a plurality of pixels PX in the display area DA. In embodiments, the display apparatus 2 may display an image through the plurality of pixels PX in the display area DA. The plurality of pixels PX of the electronic device 1 and the display apparatus 2 may include a light-emitting diode as a display element to display an image and a pixel circuit for driving the light-emitting diode.

A display element layer 10 may include the preceding display elements. Each display element may include a light-emitting diode, for example, an organic light-emitting diode including an organic emission layer. In another embodiment, the light-emitting diode may be an inorganic light-emitting diode including an inorganic material. The inorganic light-emitting diode may include a PN junction diode including inorganic semiconductor-based materials. When a voltage is applied to a PN junction diode in a forward direction, holes and electrons may be injected, and energy generated by recombination of the holes and electrons may be converted into light energy to emit light of a certain color. In some embodiments, the display element layer 10 may include a quantum-dot light-emitting diode. For example, an emission layer of the display element layer 10 may include an organic material, may include an inorganic material, may include quantum dots, may include an organic material and quantum dots, or may include an inorganic material and quantum dots.

An input sensing layer 20 may obtain coordinate information according to an external input, for example, a touch event. The input sensing layer 20 may include a touch electrode (or a sensing electrode) and trace lines connected to the touch electrode. The input sensing layer 20 may be on the display element layer 10. The input sensing layer 20 may detect an external input by using a mutual capacitance method and/or a self-capacitance method.

The input sensing layer 20 may be formed directly on the display element layer 10, or may be separately formed and then may be coupled to the display element layer 10 through an adhesive layer such as an optical clear adhesive. For example, the input sensing layer 20 may be continuously formed after a process of forming the display element layer 10, and in this case, an adhesive layer may not be located between the input sensing layer 20 and the display element layer 10.

A cover window 40 may be on the input sensing layer 20. The cover window 40 may be coupled to the input sensing layer 20 through an adhesive layer 30 including as an optical clear adhesive (OCA) located between the cover window 40 and the input sensing layer 20.

The cover window 40 may include a glass material or a plastic material. The glass material may include Ultra-thin Glass®. The plastic material may include polyethersulfone, polyacrylate, polyether imide, polyethylene naphthalate, polyethylene terephthalate, polyphenylene sulfide, polyarylate, polyimide, polycarbonate, or cellulose acetate propionate.

In one or more embodiments, one or more suitable layers having one or more suitable functions such as an optical functional layer, a physical functional layer, and a protective layer may be further located between the input sensing layer 20 and the cover window 40. Also, an adhesive layer may be selectively located between the preceding one or more suitable layers.

In order to improve a transmittance of the opening area OA, the display apparatus 2 may include a transmissive opening 2OP passing through some of layers constituting the display apparatus 2. The transmissive opening 2OP may include openings respectively passing through the display element layer 10 and the input sensing layer 20. The opening of the display element layer 10 and the opening of the input sensing layer 20 may overlap each other to form the transmissive opening 2OP of the display apparatus 2. The cover window 40 may cover the opening of the display element layer 10 and the opening of the input sensing layer 20.

The component 3 may be in the opening area OA. The component 3 may overlap the transmissive opening 2OP of the display apparatus 2. The component 3 may be under the display apparatus 2, for example, under a rear surface of the display apparatus 2. The opening area OA may be a component area (e.g., a sensor area, a camera area, and/or a speaker area) in which the component 3 for adding one or more suitable functions to the electronic device 1 is located.

The component 3 may include an electronic element. For example, the component 3 may be an electronic element using light or sound. For example, the electronic element may include a sensor that uses light such as an infrared sensor, a camera that captures an image by receiving light, a sensor that measures a distance or recognizes a fingerprint by outputting and detecting light or sound, a small lamp that outputs light, or a speaker that outputs sound. When the component 3 is an electronic element using light, the component 3 may use light of any of one or more suitable wavelength bands such as visible light, infrared light, or ultraviolet light. The opening area OA corresponds to an area through which light and/or sound output from the component 3 to the outside and/or traveling from the outside toward the component 3 may be transmitted.

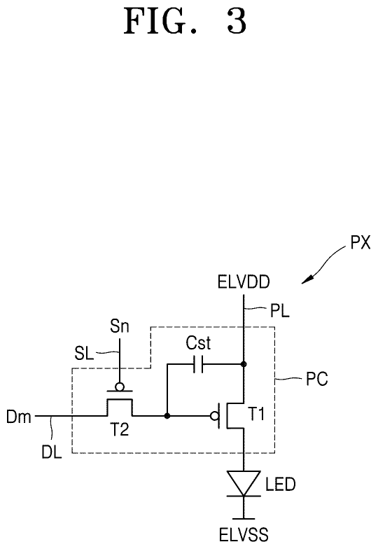

FIG. 3 is a circuit diagram schematically illustrating a light-emitting diode provided in one pixel of a display apparatus and a pixel circuit connected to the light-emitting diode, according to one or more embodiments.

Referring to FIG. 3, a pixel circuit PC may be connected to a light-emitting diode such as a light-emitting diode LED to emit light of pixels PX. The pixel circuit PC may include a first transistor T1, a second transistor T2, and a storage capacitor Cst. In one or more embodiments, the first transistor T1 may be a driving transistor, and the second transistor T2 may be a switching transistor. The second transistor T2 is connected to a scan line SL and a data line DL, and transmits a data signal Dm input through the data line DL to the first transistor T1 according to a scan signal Sn input through the scan line SL.

The storage capacitor Cst is connected to the second transistor T2 and a driving voltage line PL, and stores a voltage corresponding to a difference between a voltage received from the second transistor T2 and a driving voltage ELVDD supplied to the driving voltage line PL.

The first transistor T1 may be connected to the driving voltage line PL and the storage capacitor Cst, and may control driving current flowing from the driving voltage line PL to the light-emitting diode LED in response to a value of the voltage stored in the storage capacitor Cst. The light-emitting diode LED may emit light having a certain luminance due to the driving current.

The pixel circuit PC is not limited to the number of thin-film transistors and storage capacitors and a circuit design described with reference to FIG. 3, and the number and circuit design may be modified in one or more suitable ways.

FIG. 4 is a cross-sectional view illustrating a portion of a display area of a display apparatus, according to one or more embodiments.

Referring to FIG. 4, FIG. 4 illustrates the display element layer 10 and the input sensing layer 20 in the display area DA. The display element layer 10 may include the light-emitting diode LED as a display element of the pixel PX (see FIG. 1). In one or more embodiments, FIG. 4 may schematically illustrate a part of the pixel circuit PC described with reference to FIG. 3. For example, a thin-film transistor TFT connected to the light-emitting diode LED of FIG. 4 may be a transistor connected to the light-emitting diode LED, for example, the first transistor T1, from among the transistors illustrated in FIG. 3.

The substrate 100 may include a glass material and/or a polymer resin. In one or more embodiments, the substrate 100 may have a structure in which a base layer including a polymer resin and a barrier layer including an inorganic insulating material are alternately stacked. The polymer resin may include at least one of polyethersulfone, polyarylate, polyether imide, polyethylene naphthalate, polyethylene terephthalate, polyphenylene sulfide, polyimide, polycarbonate, cellulose triacetate, and/or cellulose acetate propionate. The inorganic insulating material may include at least one of silicon oxide (SiO₂) and/or silicon nitride (SiNₓ).

A buffer layer 101 may be on the substrate 100. The buffer layer 101 may planarize and protect a top surface of the substrate 100. The buffer layer 101 may include at least one of silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnO₂), and may have a single or multi-layer structure including the preceding material(s). In one or more embodiments, a barrier layer may be additionally located between the substrate 100 and the buffer layer 101. The barrier layer may include a material similar to that of the buffer layer 101.

An inorganic insulating layer IIL may be on the substrate 100. The inorganic insulating layer IIL may include the buffer layer 101, a gate insulating layer 103, and an interlayer insulating layer 105. Unlike in FIG. 4, the inorganic insulating layer IIL may further include an insulating layer other than the buffer layer 101, the gate insulating layer 103, and the interlayer insulating layer 105.

The buffer layer 101 may be on the substrate 100. The buffer layer 101 may planarize and protect the top surface of the substrate 100. The buffer layer 101 may include an inorganic insulating material such as silicon oxide (SiO₂), silicon nitride (SiNₓ), and/or silicon oxynitride (SiON) and may have a single or multi-layer structure including the preceding material(s). In one or more embodiments, a barrier layer may be additionally located between the substrate 100 and the buffer layer 101. In this case, the barrier layer may include a material similar to that of the buffer layer 101.

The thin-film transistor TFT may be on the buffer layer 101. As described herein, the thin-film transistor TFT may correspond to a part of the pixel circuit PC of FIG. 3, for example, the first transistor T1 (see FIG. 3). The thin-film transistor TFT may include an active layer ACT, a gate electrode GE, a source electrode SE, and a drain electrode DE. The active layer ACT may be on the buffer layer 101, and may include a drain region overlapping the drain electrode DE, a source region overlapping the source electrode SE, and a channel region between the drain region and the source region. The source region and the drain region of the active layer ACT may be regions doped with impurities.

The gate insulating layer 103 may be on the active layer ACT. The gate insulating layer 103 may include an inorganic material including oxide or nitride. For example, the gate insulating layer 103 may include at least one of silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnO₂), and may have a single or multi-layer structure including the preceding material.

The gate electrode GE may be on the gate insulating layer 103. The gate electrode GE may at least partially overlap the active layer ACT. For example, the gate electrode GE may overlap the channel region of the active layer ACT. The gate electrode GE may include at least one of aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may have a single or multi-layer structure including the preceding material(s).

The interlayer insulating layer 105 may cover the gate electrode GE. The interlayer insulating layer 105 may include an inorganic material including oxide or nitride. For example, the interlayer insulating layer 105 may include at least one of silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnO₂), and may have a single or multi-layer structure including the preceding material(s).

The gate insulating layer 103 and the interlayer insulating layer 105 may include contact holes overlapping the source region and the drain region of the active layer ACT. The source electrode SE and the drain electrode DE may be on the interlayer insulating layer 105. The source electrode SE may overlap the source region of the active layer ACT, and the drain electrode DE may overlap the drain region of the active layer ACT. The source electrode SE and the drain electrode DE may be connected to the active layer ACT through the contact holes formed in the gate insulating layer 103 and the interlayer insulating layer 105.

An organic insulating layer 107 may be on the inorganic insulating layer IIL and the thin-film transistor TFT. The organic insulating layer 107 may cover the inorganic insulating layer IIL and the thin-film transistor TFT. The organic insulating layer 107 may include a first organic insulating layer 1071 on the inorganic insulating layer IIL and a second organic insulating layer 1072 on the first organic insulating layer 1071.

The first organic insulating layer 1071 may include a contact hole overlapping the drain electrode DE. A contact metal CM may be on a top surface of the first organic insulating layer 1071, and may be coupled or connected (e.g., coupled or electrically connected) to the drain electrode DE through the contact hole of the first organic insulating layer 1071. The second organic insulating layer 1072 may include a contact hole overlapping the contact metal CM. A sub-pixel electrode 121 may be on a top surface of the second organic insulating layer 1072, and may be coupled or connected (e.g., electrically coupled or connected) to the contact metal CM through the contact hole of the second organic insulating layer 1072. Accordingly, the sub-pixel electrode 121 may be coupled or connected (e.g., electrically coupled or connected) to the drain electrode DE of the thin-film transistor TFT through the contact metal CM. Furthermore, the sub-pixel electrode 121 may be coupled or connected (e.g., electrically coupled or connected) to the active layer ACT through the drain electrode DE.

Although two organic insulating layers (e.g., the first organic insulating layer 1071 and the second organic insulating layer 1072) and one contact metal CM are illustrated in FIG. 4, the disclosure is not limited thereto. In another embodiment, N (N is a natural number of 3 or more) organic insulating layers and (N−1) contact metals may be provided. In embodiments, the organic insulating layer may be provided as a single layer, and the contact metal may not be included.

The organic insulating layer 107, for example, the first organic insulating layer 1071 and the second organic insulating layer 1072, may include at least one of a general-purpose polymer such as benzocyclobutene, polyimide, hexamethyldisiloxane, polymethylmethacrylate, or polystyrene, a polymer derivative having a phenolic group, an acrylic polymer, an imide-based polymer, an aryl ether-based polymer, an amide-based polymer, a fluorine-based polymer, a p-xylene-based polymer, or a vinyl alcohol-based polymer, and may have a single or multi-layer structure including the preceding material(s). In one or more embodiments, the first organic insulating layer 1071 and the second organic insulating layer 1072 may include the same material(s). In one or more embodiments, the first organic insulating layer 1071 and the second organic insulating layer 1072 may include different materials. In one or more embodiments, the first organic insulating layer 1071 and/or the second organic insulating layer 1072 may include a plurality of layers including different materials.

The sub-pixel electrode 121 may be on the organic insulating layer 107, for example, the second organic insulating layer 1072. The sub-pixel electrode 121 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). The sub-pixel electrode 121 may include a reflective film including silver (Ag), magnesium (Mg), aluminum (AI), platinum (Pt), palladium (Pd), gold (Au), nickel (Ni), neodymium (Nd), iridium (Ir), chromium (Cr), or a compound thereof. However, a configuration and a material of the sub-pixel electrode 121 are not limited thereto, and one or more suitable modifications may be made.

A pixel-defining layer 109 may be on the organic insulating layer 107, for example, the second organic insulating layer 1072. The pixel-defining layer 109 may cover an edge (or an edge portion) of the sub-pixel electrode 121. In embodiments, the pixel-defining layer 109 may be open to expose a central portion of the sub-pixel electrode 121. A size and a shape of an emission area of the light-emitting diode LED may be determined by an opening of the pixel-defining layer 109.

An intermediate layer 123 may be on the sub-pixel electrode 121. The intermediate layer 123 may include a common layer 123f on the pixel-defining layer 109, and an emission layer 1232 in the opening of the pixel-defining layer 109. The common layer 123f may include a first common layer 1231 on the pixel-defining layer 109 and a second common layer 1233 on the first common layer 1231. In one or more embodiments, the first common layer 1231 may be on the pixel-defining layer 109, the emission layer 1232 may be in the opening of the pixel-defining layer 109 on the first common layer 1231, and the second common layer 1233 may be on the first common layer 1231 to cover the emission layer 1232. In embodiments, the emission layer 1232 may be in the opening of the pixel-defining layer 109 and may be located between the first common layer 1231 and the second common layer 1233.

The emission layer 1232 may include an emission layer including a low molecular weight material or a high molecular weight material. The first common layer 1231 may include an electron transport layer (ETL) and/or an electron injection layer (EIL). The second common layer 1233 may include a hole transport layer (HTL) and/or a hole injection layer (HIL). In some embodiments, the first common layer 1231 or the second common layer 1232 may not be included. In some embodiments, positions of the first common layer 12131 and the second common layer 1233 may be switched.

A counter electrode 125 may be on the intermediate layer 123. For example, the counter electrode 125 may be on the second common layer 1233. The counter electrode 125 may entirely cover the intermediate layer 123. The counter electrode 125 may include a conductive material having a low work function. For example, the counter electrode 125 may include a transparent layer (or a semi-transparent layer) including silver (Ag), magnesium (Mg), aluminum (AI), platinum (Pt), palladium (Pd), gold (Au), nickel (Ni), neodymium (Nd), iridium (Ir), chromium (Cr), lithium (Li), calcium (Ca), or an alloy thereof. In embodiments, the counter electrode 125 may further include a layer including a material such as indium tin oxide (ITO), indium zinc oxide (IZO), zinc oxide (ZnO), or indium oxide (In₂O₃) on the transparent layer (or the semi-transparent layer) including the preceding material(s).

A thin-film encapsulation layer TFE may be on the counter electrode 125 and may entirely cover the light-emitting diode LED. The thin-film encapsulation layer TFE may include at least one inorganic layer and at least one organic layer. In one or more embodiments, the thin-film encapsulation layer TFE may include a first inorganic encapsulation layer 131 and a second inorganic encapsulation layer 135, and may include an organic encapsulation layer 133 located between the first inorganic encapsulation layer 131 and the second inorganic encapsulation layer 135.

Each of the first inorganic encapsulation layer 131 and the second inorganic encapsulation layer 135 may include at least one of silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnO₂). The organic encapsulation layer 133 may include a polymer-based material. Examples of the polymer-based material may include a silicon-based resin, an acrylic resin, an epoxy-based resin, polyimide, and/or polyethylene.

The input sensing layer 20 may be on the display element layer 10, for example, the thin-film encapsulation layer TFE. The input sensing layer 20 may include a touch electrode layer for detecting an external input, for example, a touch event, and a touch insulating layer between electrode layers. For example, the input sensing layer 20 may include a first touch electrode layer 201, a first touch insulating layer 203, a second touch electrode layer 205, and a second touch insulating layer 207. The first touch electrode layer 201 may be on the thin-film encapsulation layer TFE, for example, the second inorganic encapsulation layer 135 of the thin-film encapsulation layer TFE. The first touch insulating layer 203 may be on the first touch electrode layer 201. The first touch insulating layer 203 may be open to entirely cover the first touch electrode layer 201 but expose a part of a top surface of the first touch electrode layer 201. The second touch electrode layer 205 may be on the first touch insulating layer 203. The second touch electrode layer 205 may be connected to the first touch electrode layer 201 through an open portion of the first touch insulating layer 203. The second touch insulating layer 207 may be on the second touch electrode layer 205. The second touch insulating layer 207 may entirely cover the second touch electrode layer 205. In one or more embodiments, an additional insulating layer or planarization layer may be located between the first touch electrode layer 201 and the second inorganic encapsulation layer 135.

Each of the first touch insulating layer 203 and the second touch insulating layer 207 may include an organic insulating material. For example, the first touch insulating layer 203 and/or the second touch insulating layer 207 may include an acrylic organic insulating material. Each of the first touch insulating layer 203 and the second touch insulating layer 207 may be formed as a planarization layer.

The first touch electrode layer 201 and the second touch electrode layer 205 may not overlap the emission area of the light-emitting diode LED. For example, the first touch electrode layer 201 and the second touch electrode layer 205 may not overlap the emission layer 1232 of the light-emitting diode LED. In embodiments, each of the first touch electrode layer 201 and the second touch electrode layer 205 may have an opening overlapping the emission layer 1232 or the emission area of the light-emitting diode LED.

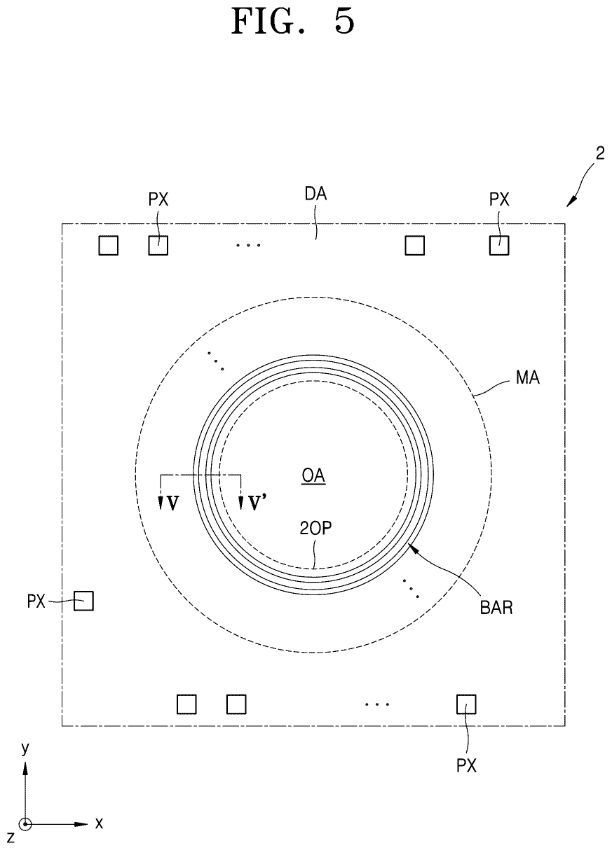

FIG. 5 is a plan view illustrating a part of a display apparatus, according to one or more embodiments.

FIG. 5 illustrates the opening area OA, the intermediate area MA, and the display area DA of the display apparatus 2. The pixels PX may be in the display area DA. The pixels PX may be in the display area DA to surround the opening area OA and the intermediate area MA. The pixel PX is a minimum area where light is emitted, and may emit light through a light-emitting diode described herein. A position of the pixel PX may be correspond to a position of the light-emitting diode. When the pixel PX is in the display area DA, it may refer to that the light-emitting diode is in the display area DA.

The pixels PX and/or the light-emitting diodes adjacent to the opening area OA may be spaced and/or apart (e.g., spaced apart or separated) from each other around the opening area OA in a plan view. The pixels PX and/or the light-emitting diodes may be vertically spaced and/or apart (e.g., spaced apart or separated) from each other around the opening area OA, or may be laterally spaced and/or apart (e.g., spaced apart or separated) from each other around the opening area OA.

At least one partition wall BAR may be in the intermediate area MA. In embodiments, at least one partition wall BAR may be located between the display area DA and the opening area OA or between the display area DA and the transmissive opening 2OP. FIG. 5 illustrates a case where two partition walls BAR are spaced and/or apart (e.g., spaced apart or separated) from each other. However, the disclosure is not limited to this number. The partition wall BAR may surround the opening area OA or the transmissive opening 2OP in a plan view (e.g., in a z-axis direction). The partition wall BAR may have a closed-loop shape in a plan view. In one or more embodiments, the partition wall BAR may have a shape that is concentric with the opening area OA or the transmissive opening 2OP in a plan view. In this case, a diameter of the partition wall BAR may be greater than a diameter of the opening area OA or the opening. In this case, when a plurality of partition walls BAR are provided, the plurality of partition walls BAR may be concentric with each other. The partition wall BAR may include an opening overlapping the opening area OA or the transmissive opening 2OP.

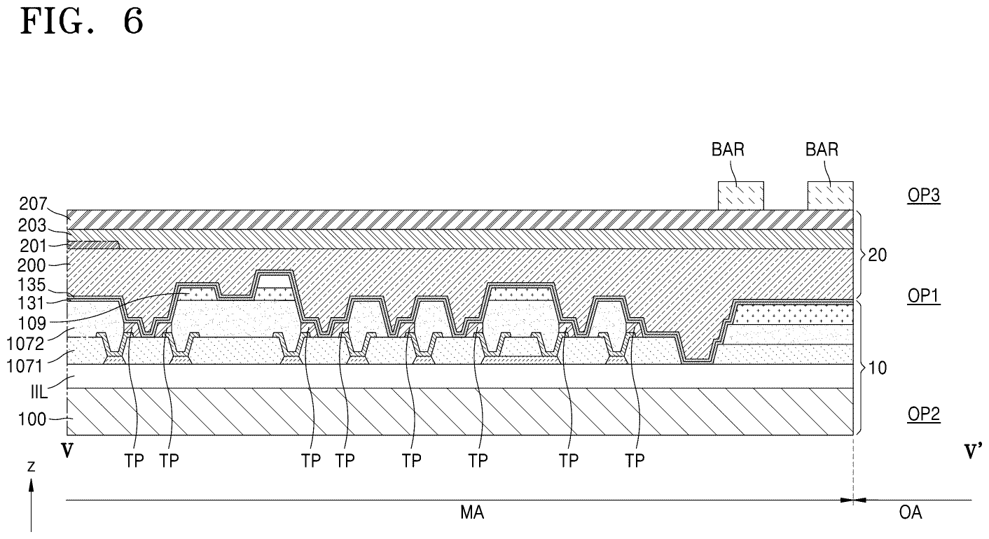

FIG. 6 is a cross-sectional view illustrating a display apparatus, according to one or more embodiments. FIG. 6 may be a cross-sectional view illustrating the display apparatus taken along line V-V′ of FIG. 5.

Referring to FIG. 6, the substrate 100, the inorganic insulating layer IIL, the first organic insulating layer 1071, the second organic insulating layer 1072, the pixel-defining layer 109, the first inorganic encapsulation layer 131, the second inorganic encapsulation layer 135, the first touch electrode layer 201, the first touch insulating layer 203, and the second touch insulating layer 207 may be in the intermediate area MA. In embodiments, the substrate 100, the inorganic insulating layer IIL, the first organic insulating layer 1071, the second organic insulating layer 1072, the pixel-defining layer 109, the first inorganic encapsulation layer 131, the second inorganic encapsulation layer 135, the first touch electrode layer 201, the first touch insulating layer 203, and the second touch insulating layer 207 may extend from the display area DA (see FIG. 4) to the intermediate area MA. The organic encapsulation layer 133 (see FIG. 4) and the second touch electrode layer 205 (see FIG. 4) may not be in the intermediate area MA.

The input sensing layer 20 may further include a planarization layer 200. The planarization layer 200 may be located between the second inorganic encapsulation layer 135 and the first touch electrode layer 201 (or the first touch insulating layer 203). The planarization layer 200 may planarize a curvature of a top surface of the second inorganic encapsulation layer 135, and may provide a flat top surface on which the first touch electrode layer 201 may be located. The planarization layer 200 may include an organic insulating material. Because the planarization layer 200 may be on the second inorganic encapsulation layer 135, when compared to the light-emitting diode LED (see FIG. 4), the planarization 200 may be on the light-emitting diode LED.

A plurality of tip structures TP may be located between the first inorganic encapsulation layer 131 and the pixel-defining layer 109. In one or more embodiments, the plurality of tip structures TP may include a conductive material (e.g., a metal). In one or more embodiments, the plurality of tip structures TP and the sub-pixel electrode 121 (see FIG. 4) may include the same material. In one or more embodiments, the plurality of tip structures TP may be formed in the same process as the sub-pixel electrode 121. In another embodiment, unlike in FIGS. 4 and 6, the plurality of tip structures TP may include the same material as the contact metal CM or the source electrode SE (and the drain electrode DE). The plurality of tip structures TP may prevent an etchant from moving toward the display area DA in an etching process described herein. Although a total of eight tip structures TP are illustrated in FIG. 6, the disclosure is not limited to this number.

A first opening OP1, a second opening OP2, and a third opening OP3 may be defined in the opening area OA. In one or more embodiments, the first opening OP1 may be defined in the inorganic insulating layer IIL, the first organic insulating layer 1071, the second organic insulating layer 1072, the pixel-defining layer 109, the first inorganic encapsulation layer 131, the second inorganic encapsulation layer 135, the planarization layer 200, the first touch insulating layer 203, and the second touch insulating layer 207. The second opening OP2 may be defined in the substrate 100. The third opening OP3 may be defined in a layer where the partition wall BAR is located. The transmissive opening 2OP (see FIG. 4) may include the first opening OP1, the second opening OP2, and the third opening OP3. The first opening OP1, the second opening OP2, and the third opening OP3 may respectively pass through layers in which the first opening OP1, the second opening OP2, and the third opening OP3 are defined. In embodiments, the first opening OP1, the second opening OP2, and the third opening OP3 may be through-holes.

The partition wall BAR may be on the second touch insulating layer 207 to be adjacent to the opening area OA. In embodiments, the partition wall BAR may be located adjacent to the first opening OP1. Although two partition walls BAR are illustrated in FIG. 6 to correspond to FIG. 5, the disclosure is not limited to this number. In one or more embodiments, as shown in FIG. 6, an edge of the partition wall BAR may be in contact with a boundary of the opening area OA. In embodiments, an edge of the partition wall BAR may be on the same plane as an edge of the second touch insulating layer 207 defining the second opening OP2. In embodiments, unlike in FIG. 6, an edge of the partition wall BAR may be spaced and/or apart (e.g., spaced apart or separated) from a boundary of the opening area OA.

In one or more embodiments, the partial wall BAR may include an organic insulating material. For example, the partition wall BAR may include an acrylic polymer. In one or more embodiments, the partition wall BAR and the second touch insulating layer 207 may include the same material.

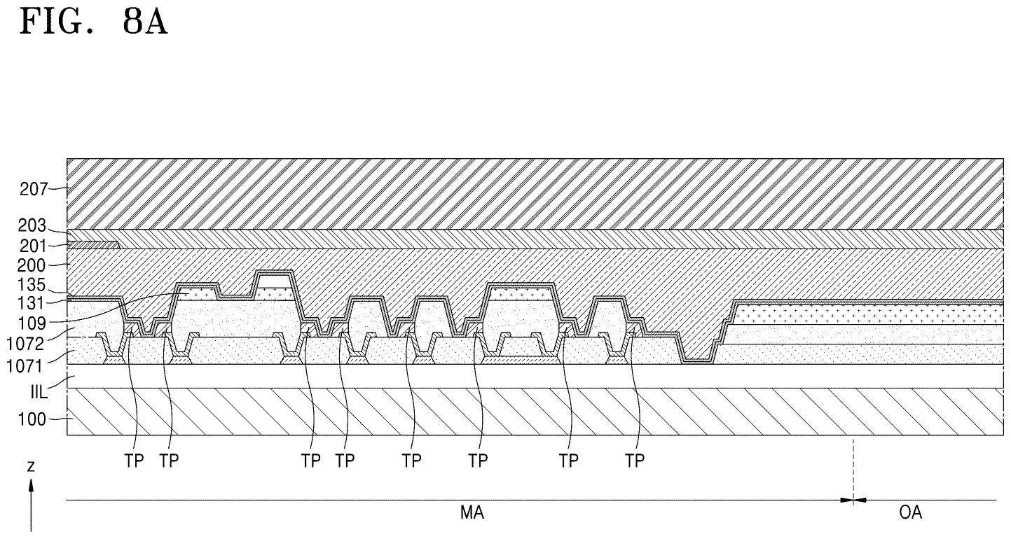

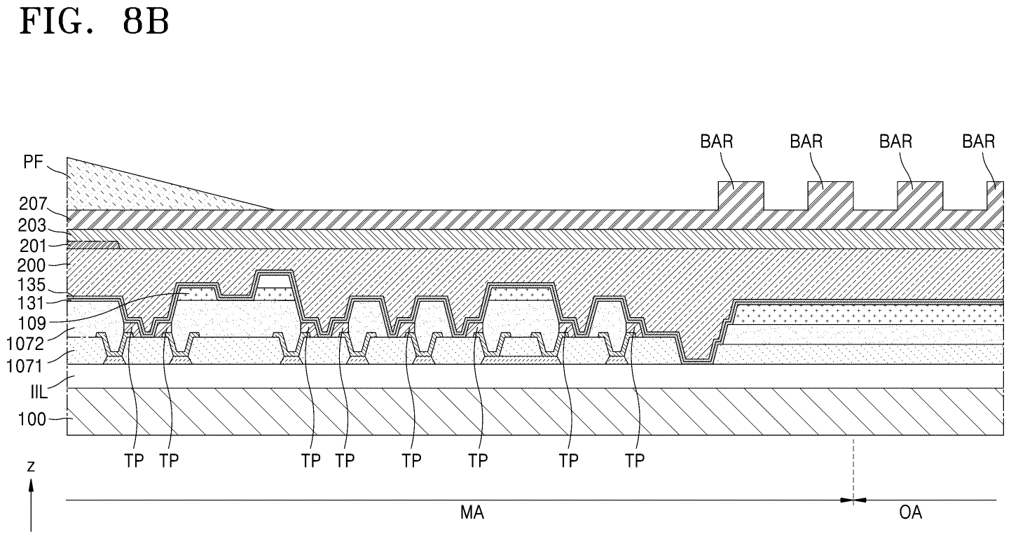

Although the second touch insulating layer 207 and the partition wall BAR are illustrated as separate layers in FIG. 6, the disclosure is not limited thereto. In one or more embodiments, the partition wall BAR may be integrally formed with the second touch insulating layer 207 as a part of the second touch insulating layer 207. Such one or more embodiments will be described herein with reference to FIGS. 8A and 8B.

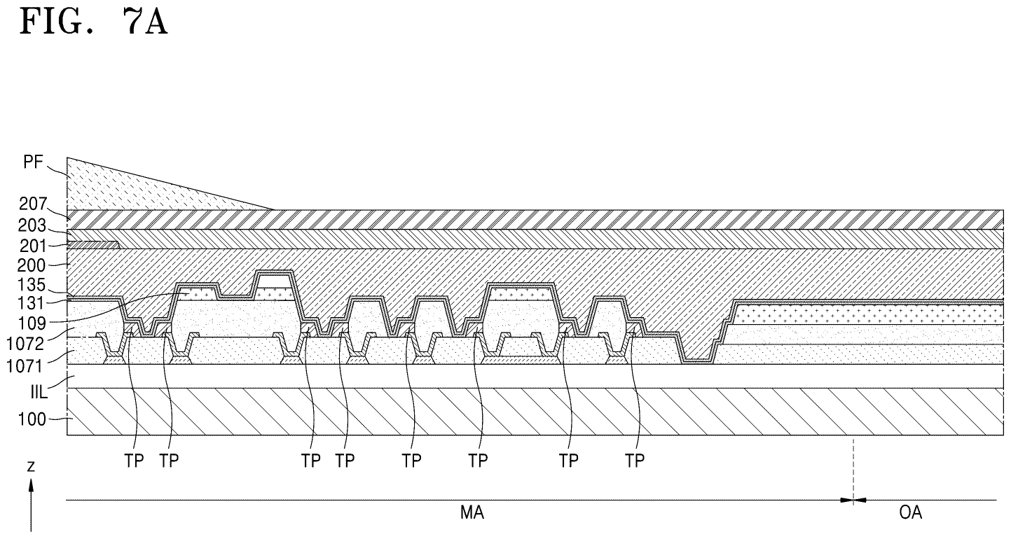

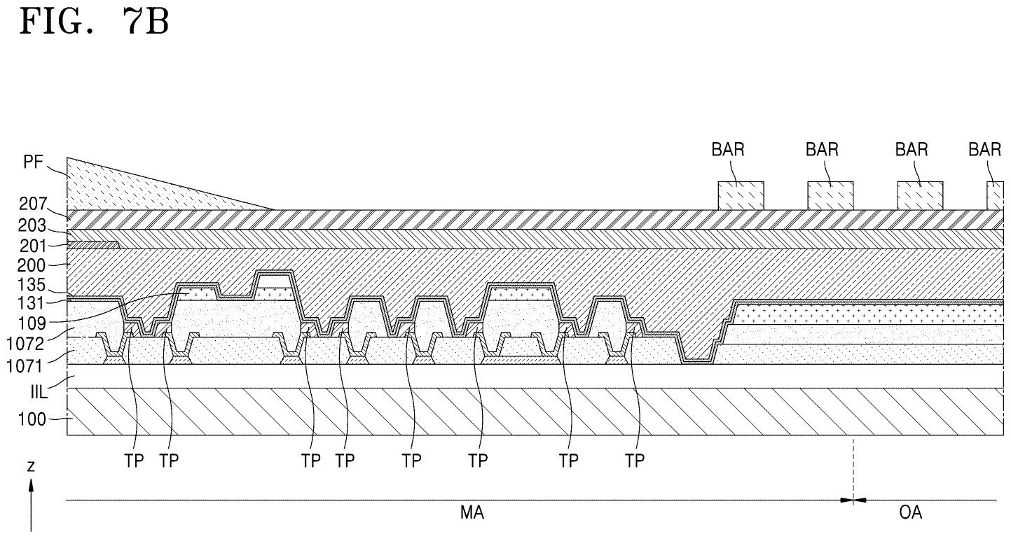

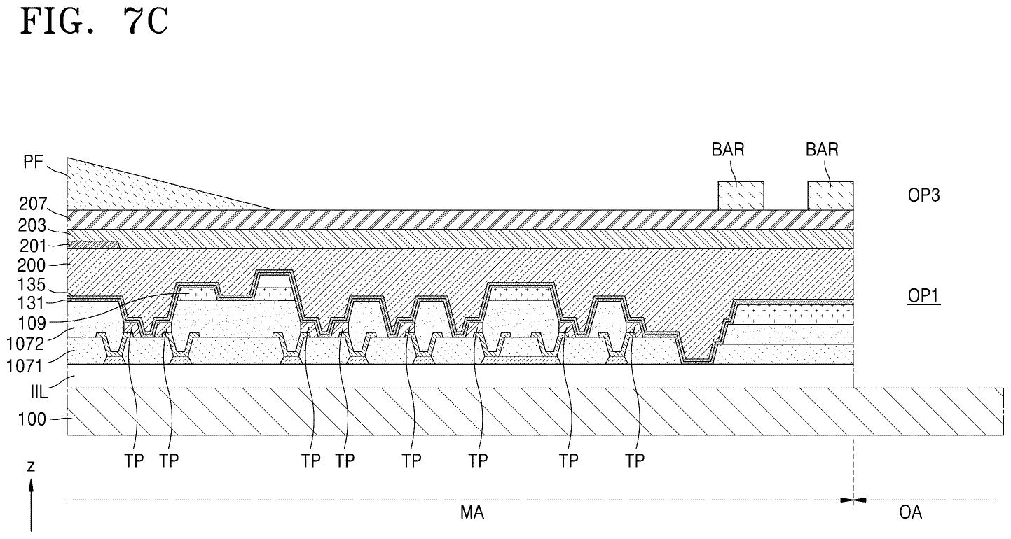

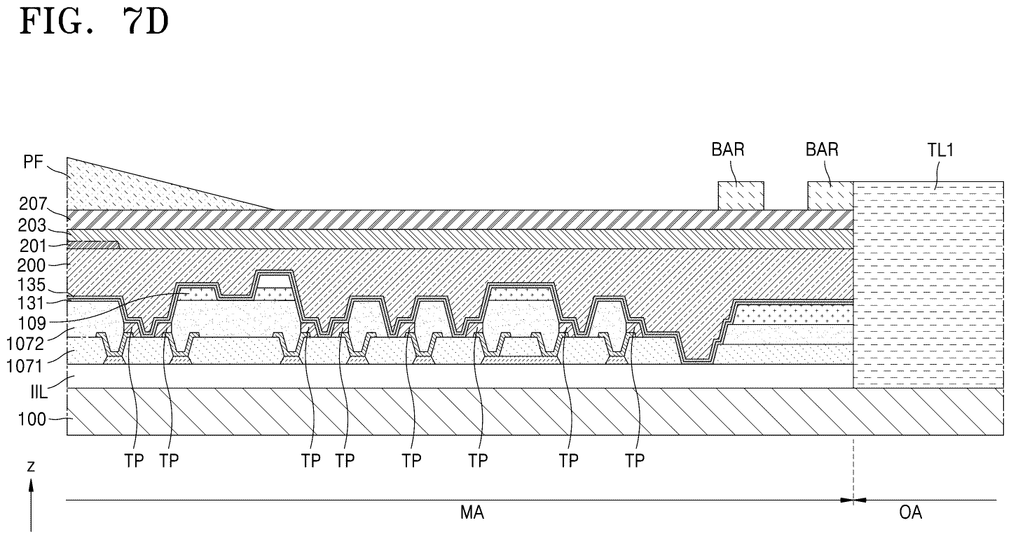

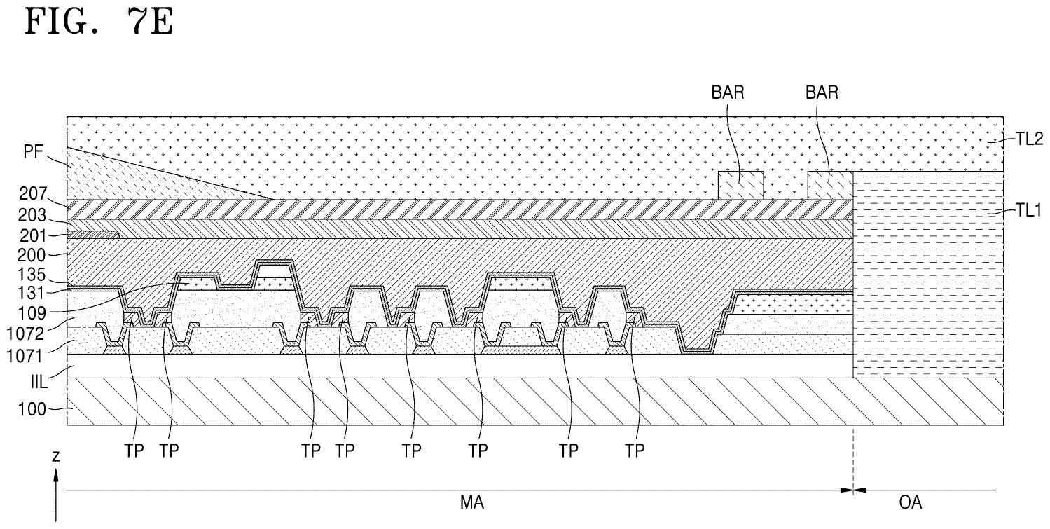

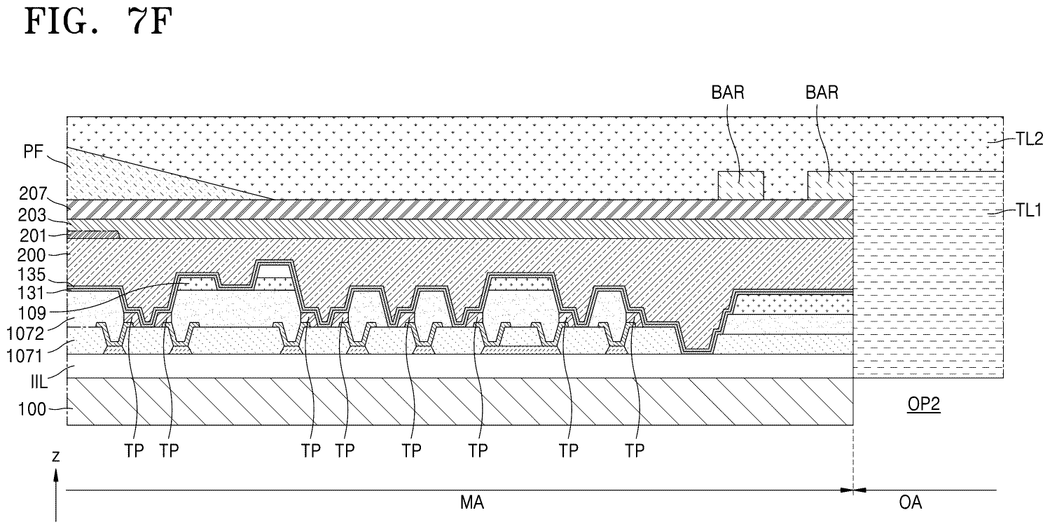

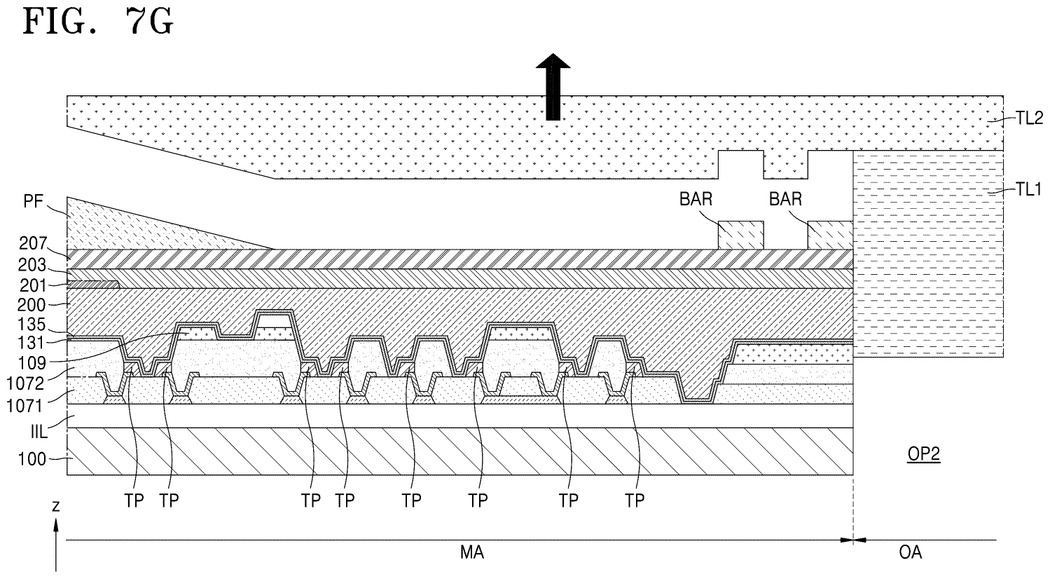

FIGS. 7A to 7G are cross-sectional views illustrating processes of a method of manufacturing a display apparatus, according to one or more embodiments.

Embodiments of FIGS. 7A to 7G illustrate a process of forming the first opening OP1, the second opening OP2, and the third opening OP3 described with reference to FIG. 6.

Referring to FIG. 7A, the inorganic insulating layer IIL, the first organic insulating layer 1071, the second organic insulating layer 1072, the pixel-defining layer 109, the first inorganic encapsulation layer 131, the second inorganic encapsulation layer 135, the planarization layer 200, the first touch electrode layer 201, the first touch insulating layer 203, and the second touch insulating layer 207 may be sequentially on the substrate 100. In one or more embodiments, the light-emitting diode LED described with reference to FIG. 4 may be formed in the display area DA in a current process.

In the current process before forming the first opening OP1, the second opening OP2, and the third opening OP3, one or more suitable layers including the substrate 100 may be located not only in the intermediate area MA but also in the opening area OA. For example, the substrate 100, the inorganic insulating layer IIL, the first organic insulating layer 1071, the second organic insulating layer 1072, the pixel-defining layer 109, the first inorganic encapsulation layer 131, the second inorganic encapsulation layer 135, the planarization layer 200, the first touch insulating layer 203, and the second touch insulating layer 207 may extend to the intermediate area MA and the opening area OA. In embodiments, in the current process, the opening area OA for forming an opening may be defined in the layers such as the substrate 100. In this case, a protective film PF may be on a top surface of the second touch insulating layer 207. The protective film PF may protect the top surface of the second touch insulating layer 207 in subsequent processes.

Referring to FIG. 7B, a plurality of partition walls BAR may be on the top surface of the second touch insulating layer 207. In one or more embodiments, the plurality of partition walls BAR may be located not only in the intermediate area MA but also in the opening area OA in the current process. However, the disclosure is not limited thereto, and in another embodiment, the plurality of partition walls BAR may be only in the intermediate area MA as shown in FIG. 6. The plurality of partition walls BAR may be spaced and/or apart (e.g., spaced apart or separated) from each other. In one or more embodiments, the plurality of partition walls BAR may have a width of about 20 micrometers (μm) to about 30 micrometers (μm) in a direction perpendicular to the z-axis. In one or more embodiments, the plurality of partition walls BAR may be spaced and/or apart (e.g., spaced apart or separated) from each other by a distance substantially equal to a width of each partition wall BAR.

Referring to FIG. 7C, in the opening area OA, the partition wall BAR, the second touch insulating layer 207, the first touch insulating layer 203, the planarization layer 200, the second inorganic encapsulation layer 135, the first inorganic encapsulation layer 131, the pixel-defining layer 109, the second organic insulating layer 1072, the first organic insulating layer 1071, and the inorganic insulating layer IIL may be removed. The removal may be performed through etching. The etching may include dry etching.

In embodiments, the first opening OP1 and the third opening OP3 overlapping the opening area OA may be formed. For example, in the opening area OA, the first opening OP1 may be formed by etching the second touch insulating layer 207, the first touch insulating layer 203, the planarization layer 200, the second inorganic encapsulation layer 135, the first inorganic encapsulation layer 131, the pixel-defining layer 109, the second organic insulating layer 1072, the first organic insulating layer 1071, and the inorganic insulating layer IIL. In the case of the partition walls BAR, closed-loop shapes as shown in FIG. 5 may be concentrically provided or arranged, and only the partition walls BAR in the opening area OA may be removed (e.g., through etching). Accordingly, the partition walls BAR having closed-loop shapes and located outside the opening area OA, that is, in the intermediate area MA, may remain, and an opening (or hole) defined by the partition walls having closed-loop shapes may be the third opening OP3.

The first opening OP1 and the third opening OP3 may be formed through the same etching process or may be formed through different etching processes.

Referring to FIGS. 7C and 7D together, a first temporary layer TL1 may be located. A part of the first temporary layer TL1 may be in the first opening OP1. For example, the first temporary layer TL1 may at least partially fill the first opening OP1. FIG. 7D illustrates one or more embodiments where the first temporary layer TL1 completely fills the first opening OP1. The first temporary layer TL1 may be in direct contact with a side surface of each of the inorganic insulating layer IIL, the first organic insulating layer 1071, the second organic insulating layer 1072, the pixel-defining layer 109, the first inorganic encapsulation layer 131, the second inorganic encapsulation layer 135, the planarization layer 200, the first touch insulating layer 203, and the second touch insulating layer 207 defining the first opening OP1.

Also, a part of the first temporary layer TL1 may be in the third opening OP3 of the partition wall BAR. For example, the first temporary layer TL1 may at least partially fill the third opening OP3. FIG. 7D illustrates one or more embodiments where the first temporary layer TL1 completely fills the third opening OP3 of the partition wall BAR. The first temporary layer TL1 may be in direct contact with a side surface of the partition wall BAR defining the third opening OP3.

The first temporary layer TL1 may be formed by being in a liquid state (e.g., resin) and then cured. For example, the first temporary layer TL1 may be formed by being sprayed in a liquid state to overlap the opening area OA through an inkjet and then cured.

However, the disclosure is not limited to a structure of the first temporary layer TL1 of FIG. 7D. In one or more embodiments, the first temporary layer TL1 may only partially fill the first opening OP1 and may not fill the third opening OP3. In one or more embodiments, the first temporary layer TL1 may completely fill the first opening OP1, but may not fill the third opening OP3. In one or more embodiments, the first temporary layer TL1 may completely fill the first opening OP1 and may partially fill the third opening OP3. In one or more embodiments, the first temporary layer TL1 may completely fill the first opening OP1 and may also completely fill the third opening OP3 (as shown in FIG. 7D).

In these embodiments, the first temporary layer TL1 may be only in the opening area OA. In this case, the partition wall BAR may function as a dam that prevents the first temporary layer TL1 from flowing beyond the opening area OA and being in the intermediate layer MA.

In another embodiment, a part of the first temporary layer TL1 in a liquid state may overflow beyond the partition wall BAR closest to the opening area OA. In this case, a plurality of partition walls BAR may be provided to prevent a part of the overflowed first temporary layer TL1 from continuously flowing in the intermediate area MA. In embodiments, the plurality of partition walls BAR may function as dams that prevent the first temporary layer TL1 in a liquid state from flowing from the opening area OA to the intermediate area MA.

Referring to FIG. 7E, a second temporary layer TL2 may be located to entirely cover the first temporary layer TL1, the partition wall BAR, and the second touch insulating layer 207. In this case, the first temporary layer TL1 and the second temporary layer TL2 may be adhered to each other. The second temporary layer TL2 may be attached as a film, or may be applied in a liquid state (e.g., resin) and then cured.

Referring to FIG. 7F, the second opening OP2 may be formed by removing a part of the substrate 100 in the opening area OA. The second opening OP2 may pass through the substrate 100. The removal may include etching. The etching may include dry etching. In one or more embodiments, the removal may include a laser ablation process. In this case, laser ablation may be performed and then etching may be performed. In one or more embodiments, the laser ablation may be performed before a process of providing or arranging the first temporary layer TL1 described with reference to FIG. 7D. The first temporary layer TL1 may prevent an etchant from penetrating into a layer other than the substrate 100 during an etching process.

Referring to FIG. 7G, the first temporary layer TL1 and the second temporary layer TL2 may be removed. Because the first temporary layer TL1 and the second temporary layer TL2 may be adhered to each other, the first temporary layer TL1 and the second temporary layer TL2 may be integrally removed. The first temporary layer TL1 and the second temporary layer TL2 may be removed by force. For example, the first temporary layer TL1 and the second temporary layer TL2 may be removed by applying a force to the first temporary layer TL1 and the second temporary layer TL2 in the z-axis direction. The force is marked by an arrow parallel to the z-axis.

There may be an adhesive force between the first temporary layer TL1 and a top surface of the second touch insulating layer 207. Accordingly, when a part of the first temporary layer TL1 is on the top surface of the second touch insulating layer 207, that is, between the second touch insulating layer 207 and the second temporary layer TL2, in a process of removing the first temporary layer TL1 and the second temporary layer TL2, a force may also be applied to the second touch insulating layer 207. This force may propagate to layers under the second touch insulating layer 207, thereby causing peeling between the layers. For example, peeling may occur between the first inorganic encapsulation layer 131 and the pixel-defining layer 109 due to the propagation of the force. In embodiments, peeling may occur between the first touch insulating layer 203 and the planarization layer 200.

Under these conditions, when the first temporary layer TL1 is located, the partition wall BAR may prevent a part of the first temporary layer TL1 from being in the intermediate area MA, that is, on the top surface of the second touch insulating layer 207, thereby preventing propagation of a force described herein. As a result, the partition wall BAR may prevent peeling between other layers due to propagation of a force when the first temporary layer TL1 and the second temporary layer TL2 are removed.

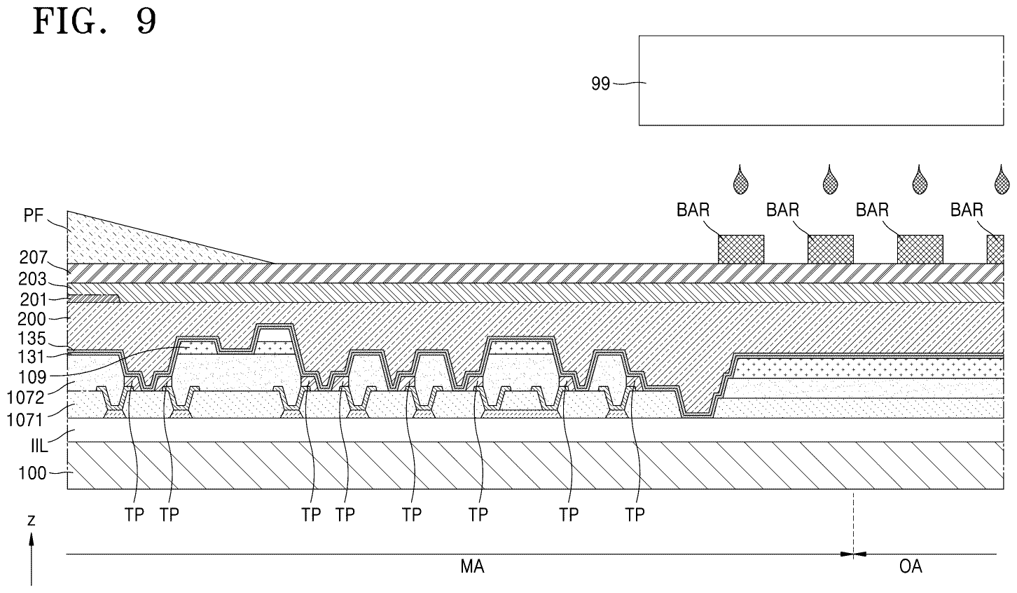

FIGS. 8A and 8B are cross-sectional views illustrating processes of a method of manufacturing a display apparatus, according to one or more embodiments. FIG. 9 is a cross-sectional view illustrating one process in a method of manufacturing a display apparatus, according to one or more embodiments.

FIGS. 8A and 8B are cross-sectional views illustrating one method of forming the partition wall described with reference to FIG. 7B. FIG. 9 is a cross-sectional view illustrating another method of forming the partition wall described with reference to FIG. 7B. These are only examples, and a method of forming a partition wall of the disclosure is not limited to the methods illustrated in FIGS. 8A, 8B, and 9.

First, referring to FIG. 8A, the second touch insulating layer 207 may be formed to have a constant thickness throughout the intermediate area MA and the opening area OA. In this case, a thickness of the second touch insulating layer 207 illustrated in FIG. 8A may be greater than a thickness of the second touch insulating layer 207 illustrated in FIG. 7B.

Referring to FIGS. 8A and 8B together, the second touch insulating layer 207 may be etched. Accordingly, the partition walls BAR may be formed in the opening area OA and the intermediate area MA adjacent to the opening area OA. In one or more embodiments, when the second touch insulating layer 207 is etched, a photomask may be used. Shapes of the partition walls BAR may be controlled through a shape of the photomask. For example, a thickness of the second touch insulating layer 207 and heights of the partition walls BAR remaining after etching may be adjusted by configuring the photomask as a full-tone or a half-tone. In the present embodiment, the partition walls BAR may include the same material as the second touch insulating layer 207. Also, the partition walls BAR may be integrally formed with the second touch insulating layer 207. For example, in the present embodiment, the second touch insulating layer 207 and the partition walls BAR may be formed substantially at the same time.

In embodiments, the partition walls BAR may be protrusions of the second touch insulating layer 207. In this case, features and effects provided by the partition walls BAR described with reference to FIGS. 7A to 7G may be provided by the protrusions of the second touch insulating layer 207 formed through the process illustrated in FIGS. 8A and 8B.

Referring to FIG. 9, the partition wall BAR may be formed by using an inkjet 99. In the present embodiment, the partition wall BAR may be sprayed in a specific shape by using the inkjet 99 and then cured. In the present embodiment, the partition wall BAR may be in a liquid state (e.g., resin). The partition wall BAR may include an organic insulating material. For example, the partition wall BAR may include an acrylic polymer. Because the partition wall BAR is located by using the inkjet 99, unlike in FIG. 9, a side surface of the partition wall BAR may be inclined with respect to a top surface of the second touch insulating layer 207. In the present embodiment, a thickness of the second touch insulating layer 207 may be substantially the same as a thickness of the second touch insulating layer 207 of FIG. 7B. In embodiments, the second touch insulating layer 207 may be completely formed and then the partition wall BAR may be located.

According to one or more embodiments, when an opening passing through a display apparatus is formed, lifting or peeling between several layers of the display apparatus may be reduced. Accordingly, the quality of the display apparatus may be improved. These effects are examples and do not limit the scope of the disclosure.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or +30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

The display apparatus, electronic device, a device of manufacturing thereof, and/or any other relevant devices or components according to embodiments of the present disclosure described herein may be implemented utilizing any suitable hardware, firmware (e.g., an application-specific integrated circuit), software, or a combination of software, firmware, and hardware. For example, the one or more suitable components of the display apparatus and/or electronic device may be formed on one integrated circuit (IC) chip or on separate IC chips. Further, the one or more suitable components of the display apparatus and/or electronic device may be implemented on a flexible printed circuit film, a tape carrier package (TCP), a printed circuit board (PCB), or formed on one substrate. Further, the one or more suitable components of the display apparatus and/or electronic device may be a process or thread, running on one or more processors, in one or more computing devices, executing computer program instructions and interacting with other system components for performing the one or more suitable functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, and/or the like. Also, a person of skill in the art should recognize that the functionality of one or more suitable computing devices may be combined or integrated into a single computing device, or the functionality of a particular computing device may be distributed across one or more other computing devices without departing from the scope of the embodiments of the present disclosure.

In the context of the present application and unless otherwise defined, the terms “use,” “using,” and “used” may be considered synonymous with the terms “utilize,” “utilizing,” and “utilized,” respectively.

A person of ordinary skill in the art, in view of the present disclosure in its entirety, would appreciate that each suitable feature of the one or more suitable embodiments of the present disclosure may be combined or combined with each other, partially or entirely, and may be technically interlocked and operated in one or more suitable ways, and each embodiment may be implemented independently of each other or in conjunction with each other in any suitable manner unless otherwise stated or implied.

It should be understood that one or more embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that one or more suitable changes in form and details may be made therein without departing from the spirit and scope as defined by the following claims and equivalents thereof.

What is claimed is:

1. A display apparatus comprising:
a substrate comprising
a display area,
an opening area in the display area, and
an intermediate area between the opening area and the display area;
a light-emitting diode in the display area and comprising:
a sub-pixel electrode,
a counter electrode, and
an intermediate layer between the sub-pixel electrode and the counter electrode;
a planarization layer on the light-emitting diode;
a first touch electrode layer on the planarization layer;
a first touch insulating layer on the first touch electrode layer;
a second touch electrode layer on the first touch insulating layer;
a second touch insulating layer on the second touch electrode layer; and
at least one partition wall adjacent to the opening area in the intermediate area and on the second touch insulating layer.

2. The display apparatus of claim 1, wherein each of the substrate, the planarization layer, the first touch insulating layer, and the second touch insulating layer comprises an opening overlapping the opening area.

3. The display apparatus of claim 1, wherein the at least one partition wall is at least partially around the opening area.

4. The display apparatus of claim 3, wherein the at least one partition wall comprises a plurality of partition walls, and the plurality of partition walls is concentrically around the opening area.

5. The display apparatus of claim 1, wherein the at least one partition wall comprises an organic insulating material.

6. The display apparatus of claim 5, wherein the at least one partition wall comprises a same material as the second touch insulating layer.

7. An electronic device comprising:
a display apparatus comprising
a display area,
an opening area in the display area, and
an intermediate area between the opening area and the display area; and
a component under a rear surface of the display apparatus and overlapping the opening area of the display apparatus,
wherein the display apparatus comprises:
a substrate;
a light-emitting diode in the display area and comprising
a sub-pixel electrode,
a counter electrode, and
an intermediate layer between the sub-pixel electrode and the counter electrode;
a planarization layer on the light-emitting diode;
a first touch electrode layer on the planarization layer;
a first touch insulating layer on the first touch electrode layer;
a second touch electrode layer on the first touch insulating layer;
a second touch insulating layer on the second touch electrode layer; and
at least one partition wall adjacent to the opening area in the intermediate area and on the second touch insulating layer.

8. The electronic device of claim 7, wherein each of the substrate, the planarization layer, the first touch insulating layer, and the second touch insulating layer comprises an opening overlapping the opening area.

9. The electronic device of claim 7, wherein the at least one partition wall is at least partially around the opening area.

10. The electronic device of claim 9, wherein the at least one partition wall comprises a plurality of partition walls, and the plurality of partition walls is concentrically around the opening area.

11. The electronic device of claim 7, wherein the at least one partition wall comprises an organic insulating material.

12. The electronic device of claim 11, wherein the at least one partition wall comprises a same material as the second touch insulating layer.

13. A method comprising:
providing, on a substrate comprising a display area, an opening area in the display area, and an intermediate area between the opening area and the display area, a light-emitting diode in the display area;
sequentially providing, on the light-emitting diode, a planarization layer, a first touch electrode layer, a first touch insulating layer, a second touch electrode layer, and a second touch insulating layer;
providing at least one partition wall adjacent to the opening area, on the second touch insulating layer;
forming a first opening overlapping the opening area, in the planarization layer, the first touch insulating layer, and the second touch insulating layer;
filling the first opening with a first temporary layer;
forming a second opening overlapping the opening area, in the substrate; and
removing the first temporary layer,
wherein the method is a method of manufacturing a display apparatus.

14. The method of claim 13, wherein the at least one partition wall is around the opening area, and a part of the first temporary layer is on a side surface of the at least one partition wall.

15. The method of claim 13, wherein the at least one partition wall comprises a third opening overlapping the opening area, and the first temporary layer at least partially fills the third opening.

16. The method of claim 13, wherein the first temporary layer is in the opening area.

17. The method of claim 13, wherein the providing of the at least one partition wall comprises providing a plurality of partition walls,
wherein a portion of the plurality of partition walls are in the opening area,
wherein the method further comprises removing the portion of the plurality of partition walls in the opening area.

18. The method of claim 13, further comprising providing a second temporary layer on the first temporary layer,
wherein the removing of the first temporary layer comprises simultaneously removing the first temporary layer and the second temporary layer.

19. The method of claim 13, wherein the at least one partition wall comprises a same material as the second touch insulating layer, and the providing of the at least one partition wall comprises etching the second touch insulating layer.

20. The method of claim 13, wherein the at least one partition wall comprises an organic insulating material, and the providing of the at least one partition wall comprises providing the at least one partition wall by using an inkjet method.
